(19) United States
(12) Patent Application Publication
(10) Pub. No.: US 2010/0123077 A1
(43) Pub. Date: May 20, 2010

(54) PASSIVE PIXEL DIRECT DETECTION SENSOR

(75) Inventors: Paul Mooney, Pleasanton, CA (US); Alexander Jozef Gubbens, Palo Alto, CA (US)

Correspondence Address: CAESAR, RIVISE, BERNSTEIN,;COHEN & POKOTILOW, LTD., 11TH FLOOR, SEVEN PENN CENTER, 1635 MARKET STREET, PHILADELPHIA, PA, 19103-2212, US

(73) Assignee: GATAN, INC., Warrendale, PA (US)

(21) Appl. No.: 12/620,979

(22) Filed: Nov. 18, 2009

Related U.S. Application Data
(60) Provisional application No. 61/115,821, filed on Nov. 18, 2008.

(51) Int. Cl. G01N 23/04; H01J 37/26

(52) U.S. Cl. 250/307; 250/311

(57) ABSTRACT

A simplification of the charge-collection pixel of an imaging detector for high-energy electrons is disclosed, incorporating removal of the buffer amplifier. While sacrificing speed and noise performance of the readout somewhat and therefore appearing counter-intuitive, this configuration has the potential to significantly reduce the susceptibility of the pixel to radiation damage.

### CROSS-REFERENCE TO RELATED APPLICATIONS

This utility application claims the benefit under 35 U.S.C. §119(e) of Provisional Application Ser. No. 61/115,821 filed on Nov. 18, 2009 and entitled Passive Pixel Direct Detection Sensor, the entire disclosure of which is incorporated by reference herein.

### FIELD OF THE INVENTION

This invention relates generally to electron microscopy.

### BACKGROUND OF THE INVENTION

Image capture on an electron microscope has traditionally been accomplished by exposing the electron image directly onto film and then processing and digitizing the film or by impinging the electron image onto a scintillator which converts the electron image into a light image transferring that image using light optics either in the form of a fused fiber optic plate onto an image sensor and then detecting and reading out that light image by the image sensor, or by first reflecting that image off a metal mirror that acts as a low backscatter beam dump and transferring that image using light optics in the form of a transfer lens onto an image sensor and then detecting and reading out that light image by the image sensor.

Both techniques are non-ideal. Film suffers from incomplete coverage of the detection area by the granular detection medium and from a relatively high admixture of noise from grain development in the case of low exposure dose. A fiber-optically coupled scintillator suffers from grain noise and from imperfect resolution of the optical coupling. In addition, the two types of optical coupling have addition drawbacks. With fiber-optical coupling which also acts as a substrate for the scintillator, electrons which have traversed the scintillator scatter in the substrate and return to the scintillator to produce additional confounding light usually at some distance from entry. Lens-coupling with a low-Z fold mirror avoids electron backscatter but suffers from the poor optical collection efficiency of even the high-numerical aperture lens suitable for image transfer over a large area through a folded optic with high resolution.

The non-ideality of traditional electron image capture methods (granularity, heaviness and poor collection efficiency) can all be addressed through the use of a low-Z semiconductor as the primary detection medium. Semiconductors such as Si have low Z compared with scintillators such as Gadolinium oxy-sulfide or YAG, are uniform through their volume in terms of efficiency at generating electron-hole pairs, and are significantly more efficient than indirect coupling methods at collecting the secondary electrons than optical coupling means which have numerical aperture and absorption issues along the coupling chain. There are several ways known to segment the volume of the detector so that lateral resolution is conferred, all relying on implants, oxides and gate structures driven to given voltages to shape the electric fields in the detection volume such that generated electrons are swept into pockets isolated one from another without dead spaces between the swept volumes. Illustration of these ways are provided by the examples of CCDs, CIDs, and CMOS active pixel sensors.

FIG. 1 shows Monte Carlo simulations of the dependence on zero-spatial-frequency (single-channel-detection) DQE(0) and backscatter fraction on atomic number (Z) of bulk materials. The calculation is based on energy deposition, not scintillation or other conversion since most of these materials will not do that. It shows that lower-Z materials produce less noise from electron scatter. It further shows that scintillators (non-elemental materials plotted against stoiciometrically-weighted average Z) have backscatter and DQE dominated by the heavier element.

Direct electron detection by semiconductor has difficulties as well, however. First, there is the issue of damage to the sensor. Ionization caused by the incident high-energy electron which occurs in the insulating layers of the device instead of in the charge-collecting parts, causes fields which alter functioning of the device, either by creating charge traps which reduce charge transfer efficiency or increase lag or by inducing increased dark current generation. Knock-on damage caused by electrons above approximately 150 kV causes dark current spikes. This damage mechanism is considerably less important in an electron detector than ionization, at least for electron energies below 500 kV. Both forms of damage have the strongest effect on CCDs due to the heavy reliance in a CCD on charge transfer. Active pixel sensors are considerably more robust than CCDs and for this reason have been used more and more extensively for high-energy particle detectors. Recently, Active Pixel Sensor (“APS”) detectors have been used in electron microscopy as well. However, data shows a limited range of usefulness due to damage mechanisms in the pixel. U.S. Pat. No. 7,262,411 shows significant rise in dark current with only 500,000 electrons of total illumination, requiring special measures such as beam-current-interlocked shuttering to limit exposure and prevent accidental exposure and annealing to release insulator-trapped charge to maintain usefulness of the detector over time. All references cited herein are incorporated by reference. The need for many tens of thousands of electrons per exposure in some applications and the rising demand for thousands of images in many applications drives a need for greater robustness than can currently be offer by APS technology.

Second, there is the problem of backscatter. Charge collection can be limited in vertical extent by the use of a thin epitaxial layer. This layer is typically between 5 and 20 um in thickness. For electron energies above 100 kV, the scattering of an incident electron will spend a significant portion of its time after having traversed the collection volume of the epitaxial layer, with many electrons returning to generate electrons a second or third time, usually at a significant distance from the original point of entry. This creates the exact same source of noise for electron imaging at kVs above 100 kV that occurs with a thin scintillator deposited on a fiber-optic substrate. However, since low-Z materials also allow the electron to travel far before stopping, the lateral spatial extent of scatter can be significantly higher than for a fiber-optic substrate.

Further problems include pre-scatter and oversensitivity. Pre-scatter: At lower kVs, the extensive structures over the APS pixel often as thick as 8 um, cause SNR degradation and resolution loss before the electrons even enter the charge-collection region. Oversensitivity: One of the advantages of direct electron detection by a semiconductor can also be a disadvantage. The number of electrons generated by an incoming primary can be so high as to saturate the charge storage capacity of a pixel after only a few primary electrons have been detected.

### DESCRIPTION OF THE DRAWINGS

FIG. 1. is a graph of a simulation indicating that Silicon, with z=14, would have zero-frequency DQE close to 95%.

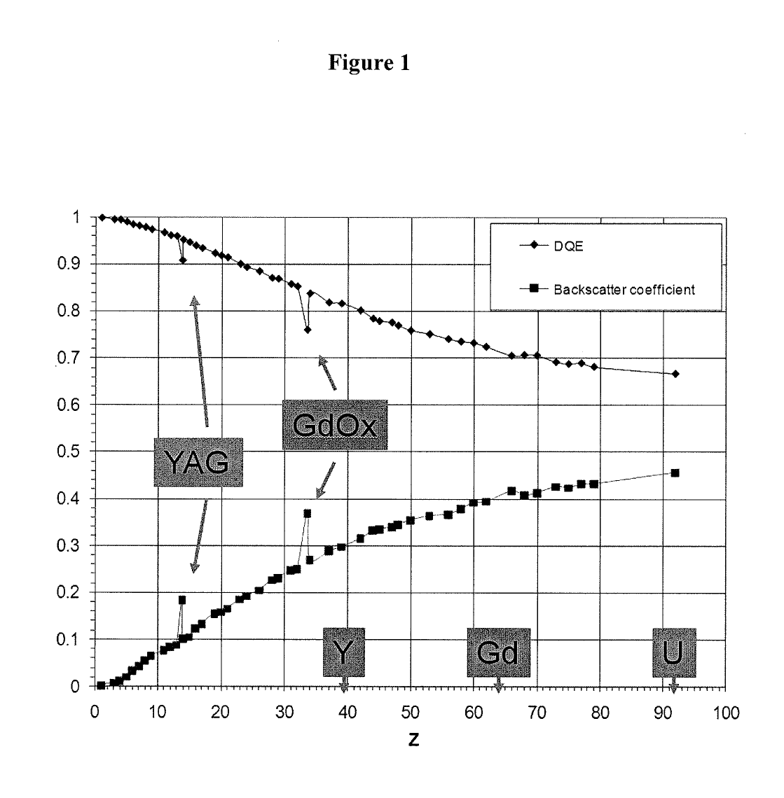

### DESCRIPTION OF THE PREFERRED EMBODIMENT OF THE INVENTION

In an embodiment, a simplification of the charge-collection pixel of an imaging detector for high-energy electrons is accomplished by removal of the buffer amplifier used in prior art active pixel sensors. This configuration, while sacrificing speed and noise performance of the readout somewhat and therefore appearing counter-intuitive, has the potential to significantly reduce the susceptibility of the pixel to radiation damage. The resultant non-active (or passive) pixel sensor could then possibly meet the needs of a broader group of users than just those in the extreme low-dose field. The simpler pixel also has the potential to reduce the “pre-scatter” discussed above, which is important for low-voltage electron imaging by reducing the complexity of structures needed over the pixel.

Of course with that primary mitigation, other mitigations allowing further increases in dose tolerance would be of clear benefit, namely
a. beam-intensity-interlocked or shutter-based sensor shuttering
b. annealing for removal of charge buildup
c. thinning to reduce the incremental oxide dose caused by non-information-bearing backscatter. This measure also addresses the issues of backscatter noise and resolution loss and oversensitivity.

Partial recovery of readout speed and noise performance through the use of multi-pixel shared buffer amplifiers.

1. An imaging sensor comprising,
a plurality of charge collection pixels, each of said charge collection pixels not having an individual buffer amplifier.

2. An imaging sensor for detection of high energy electrons comprising,
a plurality of charge collection pixels, each of said charge collection pixels not having an individual buffer amplifier.

3. The imaging sensor of claim 2, further comprising a shutter.

4. The imaging sensor of claim 3, wherein said shutter is a beam intensity interlock.

5. The imaging sensor of claim 2, wherein said sensor is periodically annealed to remove charge buildup.

6. The imaging sensor of claim 2, wherein said sensor comprises a thinned substrate.

7. A method for producing an image formed by high energy electrons, comprising:
exposing an image sensor comprised of charge collection pixels to said high energy electrons, wherein each of said charge collection pixels does not have an individual buffer amplifier.

8. The method of claim 7, further comprising shuttering said image sensor to reduce damage from the high energy electrons.

9. The method of claim 7, wherein said imaging sensor comprises a thinned substrate.

10. The method of claim 7, further comprising, periodically annealing said sensor to remove charge build-up.
